(19) United States
(12) Patent Application Publication
(10) Pub. No.: US 2006/0182589 A1
(43) Pub. Date: Aug. 17, 2006

(54) PLATE SUPPORT HAVING MOVABLE RIBS FOR ADJUSTING AND GUIDING A WAFER

(76) Inventor: Pi-Tang Chiu, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 10/905,793

(22) Filed: Jan. 20, 2005

(51) Int. Cl. H01L 21/687

(52) U.S. Cl. 414/672

(57) ABSTRACT

A plate support for placing a wafer and controlling temperature variations of the wafer has a platform for placing the wafer, a vacuum for drawing air out from passages in the platform, a detector for detecting air pressure in the passages, a plurality of pins for holding the wafer, and a plurality of movable ribs for adjusting and guiding the wafer on the plane platform by contacting a rim of the wafer. When the pins descend, the ribs move forward to the center of the plane platform to adjust the wafer.

### BACKGROUND OF INVENTION

1. Field of the Invention

The present invention relates to a plate support for placing a wafer and controlling temperature variations of the wafer, and more particularly to a plate support for placing a wafer and controlling temperature variations of the wafer.

2. Description of the Prior Art

In the fabrication of an integrated circuit, for example, a circuit pattern is formed by so-called photolithography technology in which a semiconductor substrate (wafer) is coated with a coating solution such as a photo-resist solution to form a resist film and in which the resist film is exposed correspondingly to the circuit pattern and developed.

During the coating process, a plurality plate supports are used to heat and cool the coated wafer to control the thickness of photo-resist layer on the wafer. The plate support for heating the wafer during the coating process is defined as a low-temperature heating plate (LHP), and the plate support for cooling the wafer during the coating process is defined as a cooling process plate (CPL). However, because the prior art plate supports are not well designed, the wafer cannot be properly heated and cooled when proceeding the coating process. The thickness of photo-resist layer on the wafer, hence, cannot be well controlled.

Please refer to FIGS. 1-2, which FIG. 1 is a schematic diagram of a plate support 10 according to the prior art, and FIG. 2 is a cross-sectional diagram of the plate support 10 along a dotted line 2-2 shown in FIG. 1. The plate support 10 comprises a platform 12 for placing a wafer 22. A plurality of passages 16 are formed in the platform 12. The plate support 10 further comprises a plurality of guides 14 for guiding the wafer 22 on the platform 12 and a plurality of pins 18 for holding the wafer 22 during placing the wafer 22 on the platform 12. The pins 18 pass through the passages 16. When the pins 18 hold the wafer 22 and descend, the wafer 22 descends at the same time. However, because of the guides 14, the wafer 22 may be slanted and does not properly contact with the surface 20 of the platform 12. In this condition, the wafer 22 cannot be effectively heated or cooled and the thickness of photo-resist layer on the wafer 22, hence, cannot be well controlled.

### SUMMARY OF INVENTION

It is therefore an objective of the present invention to provide a plate support having movable ribs for adjusting and guiding a wafer to solve the above-mentioned problems.

The plate support is used to place a wafer and control temperature variations of the wafer. The plate support has a platform for placing the wafer, a vacuum for drawing air out from passages in the platform, a detector for detecting air pressure in the passages, a plurality of pins for holding the wafer, and a plurality of movable ribs for adjusting and guiding the wafer on the plane platform by contacting a rim of the wafer. When the pins descend, the ribs move forward to the center of the plane platform to adjust the wafer.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram of a plate support according to the prior art.

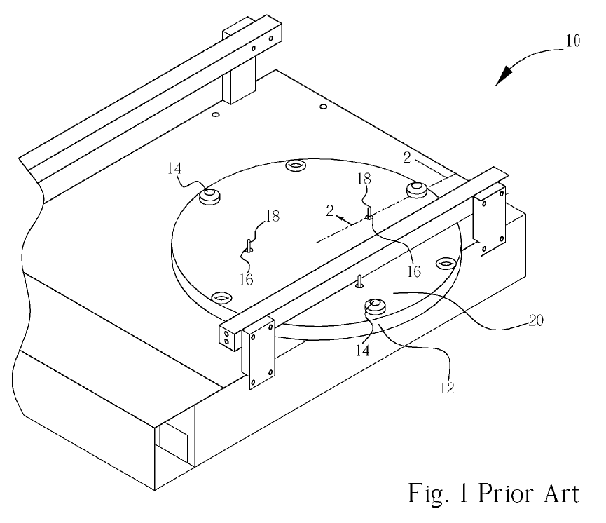

FIG. 2 is a cross-sectional diagram of the plate support along a dotted line 2-2 shown in FIG. 1.

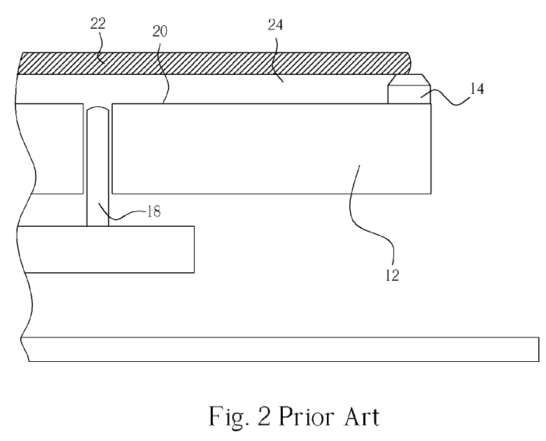

FIG. 3 is a schematic diagram of a plate support according to the present invention.

FIG. 4 is a functional diagram of the plate support.

FIG. 5 is a cross-sectional diagram of the plate support along a dotted line 5-5 shown in FIG. 3.

FIG. 6 is a cross-sectional diagram of the plate support when pins of the plate support descend.

FIG. 7 is a schematic diagram of a vacuum, a vacuum detector, and the wafer shown in FIG. 4.

### DETAILED DESCRIPTION

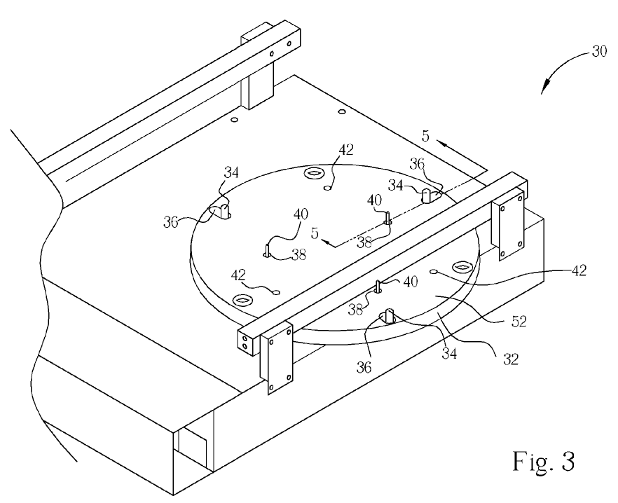

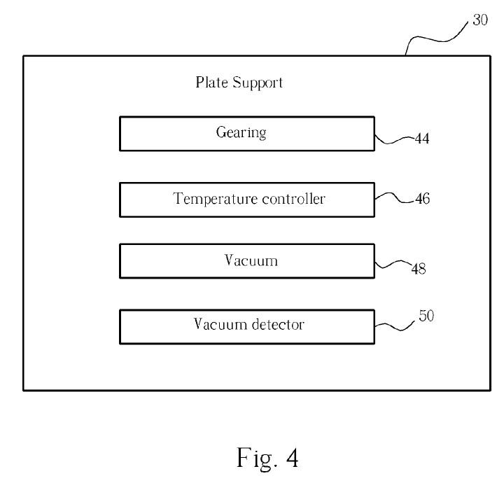

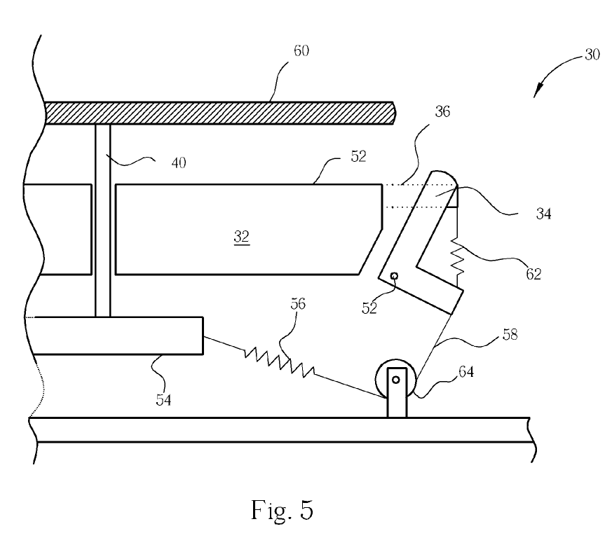

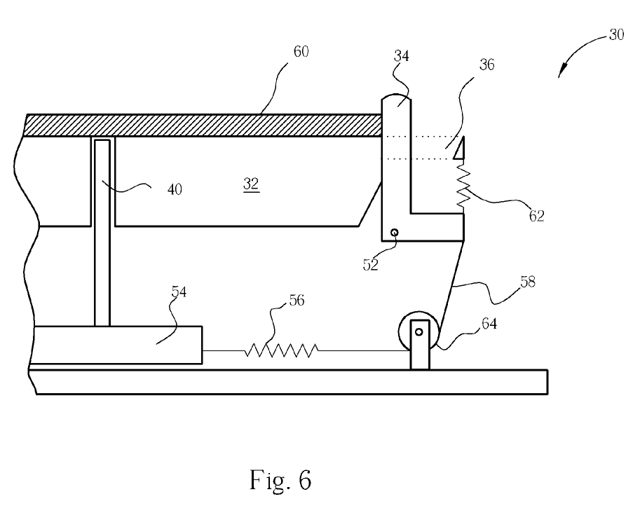

Please refer to FIGS. 3-6, which FIG. 3 is a schematic diagram of a plate support 30 according to the present invention, FIG. 4 is a functional diagram of the plate support 30, FIG. 5 is a cross-sectional diagram of the plate support 30 along a dotted line 5-5 shown in FIG. 3, and FIG. 6 is a cross-sectional diagram of the plate support 30 when pins 40 descend. The plate support 30 comprises a platform 32 for placing a wafer 60. A plurality of passages 36, 38, and 42 are formed in the platform 32. The plate support 30 further comprises a plurality of moveable L-shaped ribs 34 for adjusting and guiding the wafer 22 on the platform 32 by contacting a rim of the wafer 60. The ribs 34 pass through the passages 36 and respectively rotate along a corresponding axis 52. The plate support 30 further comprises a plurality of pins 40 for holding the wafer 60 during placing the wafer 60 on the platform 32. The pins 40 pass through the passages 38. When the pins 40 hold the wafer 60 and descend, the wafer 60 descends and the ribs 34 move forward to the center of the plane platform 32 at the same time. In addition, the plate support 30 further comprises a gearing 44 for driving the ribs 34 and a temperature controller 46 for controlling temperature variations of the wafer 60 while the wafer 60 is placed on the surface 52 of the platform 32.

Please refer to FIGS. 5-6. The pins 40 connect with a hoist 54, and each of the ribs 34 connects with the hoist 54 via a spring 56 and a rope 58. The spring 56 and the rope 58 contact with a wheel 64. In addition, one end of each rib 34 connects with one end of the passage 36 via another spring 62. Therefore, as shown in FIG. 6, when the pins 40 descend, the ribs 34 move forward to the center of the plane platform 32 to adjust and guide the wafer 60 on the platform 32. And as shown in FIG. 5, when the pins 40 rise, the ribs move backward to release the wafer 60. Therefore, when the pins 40 descend, the wafer properly contacts with the surface 52 of the platform 32. In this condition, the wafer 60 is effectively heated or cooled by the temperature controller 46, and the thickness of photo-resist layer on the wafer 60, hence, is well controlled.

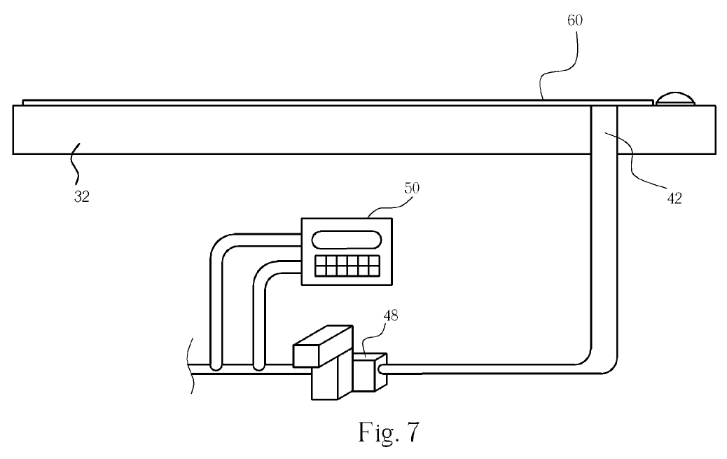

Please refer to FIGS. 3, 4, and 7, which FIG. 7 is a schematic diagram of a vacuum 48, a vacuum detector 50, and the wafer 60 on the platform 32. The plate support 30 has the vacuum 48 and the vacuum detector 50. The vacuum 48 and the vacuum detector 50 connect with the passages 42. When the wafer 60 is placed on the platform 32, the vacuum 48 draws air out from the passages 42 and the vacuum detector 50 detects air pressure in the passages 42. If the air pressure detected by the vacuum detector 50 is less than a predetermined value, it means that the wafer 60 properly contacts with the platform 32. On the other hand, if the air pressure detected by the vacuum detector 50 is greater than the predetermined value, it means that the wafer 60 does not properly contact with the platform 32. Therefore, with the help of the vacuum 48 and the vacuum detector 50, the wafer 60 can be accurately placed on the platform 32.

Compared with the prior art, the plate support according to the present invention has a plurality of movable ribs to adjust and guide a wafer on the plane platform by contacting a rim of the wafer. In addition, the plate support further comprises a vacuum 48 and a vacuum detector for determining whether the wafer properly contacts with a platform of the plate support. Therefore, the coated wafer can be accurately placed on the platform of the plate support.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A plate support for placing a wafer and controlling temperature variations of the wafer, the plate support comprising:
a platform for placing the wafer, a plurality of passages being formed in the plane platform;
a vacuum for drawing air out from the passages;
a detector for detecting air pressure in the passages;
a plurality of pins for holding the wafer; and
a plurality of movable ribs for adjusting and guiding the wafer on the plane platform by contacting a rim of the wafer;
wherein the ribs move forward to the center of the plane platform to adjust the wafer when the pins descend.

2. The plate support of claim 1 wherein the ribs move backward to release the wafer when the pins rise.

3. The plate support of claim 1 wherein each of the ribs is connected to a corresponding one of the pins via a connection element.

4. The plate support of claim 3 wherein the connection element is a spring.

5. The plate support of claim 1 wherein the plate platform has a heating device for heating the wafer.

6. The plate support of claim 1 wherein the plate platform has a cooling device for cooling the wafer.

7. The plate support of claim 1 wherein each of the pins passed through a corresponding one of passages formed in the plane platform when holding the wafer.

8. A plate support for placing a wafer and controlling temperature variations of the wafer, the plate support comprising:
a platform for placing the wafer;
a plurality of pins for holding the wafer; and
a plurality of movable ribs for adjusting and guiding the wafer on the plane platform by contacting a rim of the wafer;
wherein the ribs move forward to the center of the plane platform to adjust the wafer when the pins descend.

9. The plate support of claim 1 wherein the ribs move backward to release the wafer when the pins rise.

10. The plate support of claim 1 wherein a plurality of passages formed in the plane platform, each of the passages connects to a vacuum and a detector, the vacuum draws air out from the passages and the detector detects air pressure in the passages.

11. The plate support of claim 1 wherein each of the ribs is connected to a corresponding one of the pins via a connection element.

12. The plate support of claim 11 wherein the connection element is a spring.

13. The plate support of claim 1 wherein the plate platform has a heating device for heating the wafer.

14. The plate support of claim 1 wherein the plate platform has a cooling device for cooling the wafer.

15. The plate support of claim 1 wherein each of the pins passed through a corresponding one of passages formed in the plane platform when holding the wafer.
